(19) United States
(12) Patent Application Publication
(10) Pub. No.: US 2026/0190793 A1
(43) Pub. Date: Jul. 2, 2026

(54) DISPLAY APPARATUS

(71) Applicant: LG Display Co., Ltd., Seoul (KR)

(72) Inventors: ChangDuk HA, Gumi-si (KR); Soobin BAE, Paju-si (KR)

(73) Assignee: LG Display Co., Ltd., Seoul (KR)

(21) Appl. No.: 19/383,421

(22) Filed: Nov. 7, 2025

(30) Foreign Application Priority Data
Dec. 26, 2024 (KR) 10-2024-0196885

(51) Int. Cl. H10K 59/80; H10K 59/122; H10K 59/40

(52) U.S. Cl. CPC H10K 59/8731; H10K 59/122; H10K 59/40

(57) ABSTRACT

A display apparatus can include a substrate having an active area, a first non-active area enclosing the active area, a bending area extending from the first non-active area to be bent, and a second non-active area extending from the bending area. The display apparatus can further include a plurality of light emitting diodes disposed in the active area on the substrate and each having an anode, an organic layer and a cathode, a bank disposed to cover an end of the anode, and a cover layer disposed on the bank and extending from the active area to the first non-active area. The organic layer is disposed to cover the cover layer on the bank.

### CROSS-REFERENCE TO RELATED APPLICATIONS

This application claims priority to Korean Patent Application No. 10-2024-0196885 filed on December 26, 2024, in the Korean Intellectual Property Office, the entire disclosure of which is incorporated by reference into the present application.

### BACKGROUND

### Field

The present disclosure relates to a display apparatus, and more particularly, to a display apparatus which is capable of minimizing a moisture permeation defect and implementing a narrow bezel.

### Description of the Related Art

As the world enters the information era, a field of a display apparatus which visually expresses electrical information signals has been rapidly developed and studies are continued to improve performances of various display apparatuses, such as a thin-thickness, a light weight, and low power consumption.

A representative display apparatus can include a liquid crystal display apparatus (LCD), a field emission display apparatus (FED), an electro-wetting display apparatus (EWD), and an organic light emitting display apparatus (OLED).

An electroluminescent display apparatus which is represented by an organic light emitting display apparatus is a self-emitting display apparatus where a separate light source is not needed, which is different from a liquid crystal display apparatus. Therefore, the electroluminescent display apparatus can be manufactured to have a light weight and a thin thickness. Further, since the electroluminescent display apparatus is advantageous not only in terms of power consumption due to the low voltage driving, but also in terms of color implementation, a response speed, a viewing angle, and a contrast ratio (CR), it is expected to be utilized in various fields.

### SUMMARY OF THE DISCLOSURE

An object to be achieved by the present disclosure is to provide a display apparatus in which a cover layer covering a component in an active area and a non-active area adjacent to a bending area is disposed to prevent or minimize a moisture permeation defect.

Another object to be achieved by the present disclosure is to provide a low power display apparatus in which a lifespan is improved and power consumption is reduced by improving the reliability of the display apparatus by minimizing or preventing the moisture permeation defect.

Still another object to be achieved by the present disclosure is to provide a display apparatus which minimizes a margin distance needed to place a cover layer which covers a component therebelow to implement a narrow bezel.

Objects of the present disclosure are not limited to the above-mentioned objects, and other objects, which are not mentioned above, can be clearly understood by those skilled in the art from the following descriptions.

According to an aspect of the present disclosure, a display apparatus includes a substrate which includes an active area, a first non-active area enclosing the active area, a bending area extending from the first non-active area to be bent, and a second non-active area extending from the bending area; a plurality of light emitting diodes which is disposed in the active area on the substrate and each includes an anode, an organic layer, and a cathode; a bank which is disposed so as to cover an end of the anode; and a cover layer which is disposed on the bank and is disposed to extend from the active area to the first non-active area, and the organic layer is disposed so as to cover the cover layer on the bank.

According to another aspect of the present disclosure, a display apparatus includes: a substrate which includes an active area in which a plurality of sub pixels is disposed, a first non-active area enclosing the active area, a bending area extending from the first non-active area to be bent, and a second non-active area extending from the bending area; a plurality of light emitting diodes which is disposed in the plurality of sub pixels on the substrate and each includes a plurality of anodes, an organic layer, and a cathode; a bank which is disposed so as to expose a part of the anodes on the plurality of anodes; a first cover layer which is disposed to extend from the active area to the first non-active area and is disposed between the bank and the organic layer; and a plurality of dams which is disposed so as to enclose the active area in the first non-active area, and the first cover layer is disposed so as to cover the plurality of dams.

Other detailed matters of the example embodiments of the present disclosure are included in the detailed description and the drawings.

In the display apparatus according to aspects of the present disclosure, an upper portion of a plurality of transistors disposed in an active area and an upper portion of a plurality of dams disposed in a non-active area adjacent to a bending area are covered to prevent or minimize a moisture permeation defect of an active area and a non-active area adjacent to a bending area.

In the display apparatus according to aspects of the present disclosure, a moisture permeation defect is minimized or prevented to improve the reliability and the lifespan of the display apparatus, thereby implementing a low-power display apparatus with reduced power consumption.

In the display apparatus according to aspects of the present disclosure, when a cover layer which covers components in an active area and a non-active area adjacent to a bending area is formed, a process method with an improved precision is used to minimize a margin distance needed to place the cover layer.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display apparatus according to one or more example embodiments of the present disclosure;

FIG. 2 is a cross-sectional view taken along line A-A' of FIG. 1 according to an example of the present disclosure;

FIG. 3 is a cross-sectional view taken along line B-B' of FIG. 1 according to an example of the present disclosure; and

FIG. 4 is a cross-sectional view taken along line C-C' of FIG. 1 according to an example of the present disclosure.

### DETAILED DESCRIPTION OF THE EMBODIMENTS

Advantages and characteristics of the present disclosure and method(s) of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as 'including', 'having', 'consist of,' etc. used herein are generally intended to allow other components to be added unless the terms are used with the term 'only'. Any references to singular can include plural unless expressly stated otherwise.

Components are interpreted to include an ordinary error range even if not expressly stated.

When the position relation between two parts is described using the terms such as 'on', 'above', 'below', 'next', one or more parts can be positioned between the two parts unless the terms are used with the term 'immediately' or 'directly'.

When an element or layer is disposed "on," “over,” “above,” etc. another element or layer, the element or layer can be disposed directly on the another element or layer, or another element or layer can be interposed therebetween.

Although the terms such as "first", "second", and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may” and vice versa.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings. All the components of each display apparatus/device according to all embodiments of the present disclosure are operatively coupled and configured.

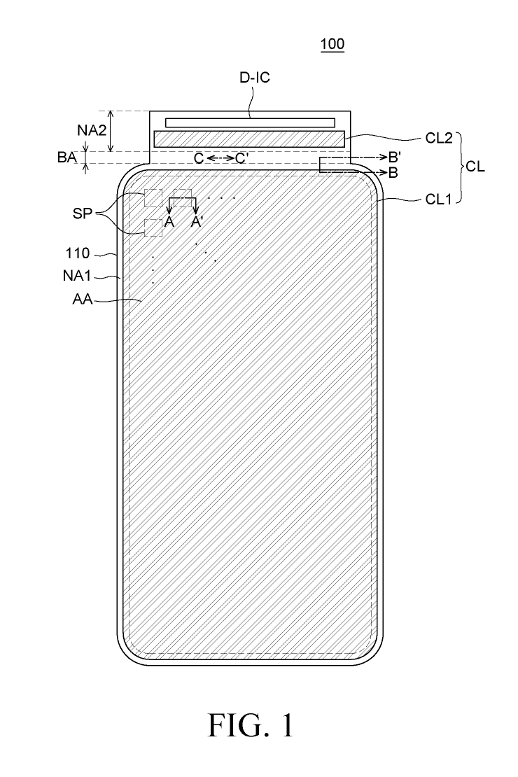

FIG. 1 is a plan view of a display apparatus according to one or more example embodiments of the present disclosure.

Referring to FIG. 1, a display apparatus 100 according to an example embodiment of the present disclosure is a device which displays an image to a user. In the display apparatus 100, a display element which displays images, a driving element which drives the display element, and wiring lines which transmit various signals to the display element and the driving element can be disposed.

The display element can be defined in different manners depending on the type of the display apparatus 100. For example, when the display apparatus 100 is an organic light emitting display apparatus, the display element can be an organic light emitting diode which includes an anode, an organic layer, and a cathode. For example, when the display apparatus 100 is a liquid crystal display apparatus, the display element can be a liquid crystal display element. Hereinafter, it is assumed that the display apparatus 100 is an organic light emitting display apparatus, but the display apparatus 100 is not limited to the organic light emitting display apparatus.

The substrate 110 includes an active area AA and a non-active area.

The active area AA is an area in which images are displayed in the substrate 110. In the active area AA, a plurality of sub pixels SP which configures a plurality of pixels and a driving circuit for driving the plurality of sub pixels SP can be disposed.

The plurality of sub pixels SP is minimum units which configure the active area AA and a display element can be disposed in each of the plurality of sub pixels SP. For example, an organic light emitting diode which includes an anode, an organic layer, and a cathode can be disposed in each of the plurality of sub pixels SP, but it is not limited thereto. Further, the driving circuit for driving the plurality of sub pixels SP can include a driving element and a wiring line. For example, the driving circuit can be configured by a thin film transistor, a storage capacitor, a gate line, and a data line, but is not limited thereto.

The non-active area is an area in which no image is displayed. The non-active area can refer to an outer peripheral portion of the substrate 110 which encloses the active area AA. The non-active area can overlap a black matrix. In the non-active area, various wiring lines and circuits for driving an organic light emitting diode in the active area AA are disposed. For example, in the non-active area, a link line which transmits signals to the plurality of sub pixels SP and driving circuits of the active area AA or a driving IC D-IC such as a gate driver IC or a data driver IC can be disposed, but it is not limited thereto.

The non-active area includes a first non-active area NA1, a bending area BA, and a second non-active area NA2.

The first non-active area NA1 is an area which encloses the active area AA and extends from the active area AA. The bending area BA can extend from one side of the first non-active area NA1 and can be bent. The second non-active area NA2 is an area which extends from the bending area BA to be disposed below the active area.

The first non-active area NA1 and the second non-active area NA2 are disposed on the same plane as the active area AA or disposed to be parallel to the active area AA and maintain a flat state. For example, the first non-active area NA1 can be disposed to be flat on the same plane as the active area AA and the second non-active area NA2 can be disposed below the active area AA to be parallel to the active area AA and be flat. Therefore, the active area AA, the first non-active area NA1, and the second non-active area NA2 can be referred to as non-bending areas, but are not limited thereto.

In the second non-active area NA2, a driving integrated circuit (IC) D-IC is disposed. The driving IC D-IC can supply a data signal to the plurality of sub pixels SP. For example, the driving IC D-IC samples and latches the data signal supplied from the timing controller in response to a data timing control signal supplied from the timing controller to convert the data signal into a gamma reference voltage and output the converted gamma reference voltage. The driving IC D-IC can output a data signal through the plurality of data lines. For example, in the second non-active area NA2 in which the driving IC D-IC is disposed, a pad unit is disposed and a printed circuit board which is electrically connected to the pad unit is further disposed to supply a signal to the driving IC D-IC, but is not limited thereto.

In the meantime, the driving IC D-IC is disposed on one side of the substrate 110 in a chip on panel (COP) manner to be connected to the display panel or is disposed in a separate flexible film to be connected to the substrate 110 in a chip on film (COF) manner. In the display apparatus 100 according to the example embodiment of the present disclosure, it is assumed that the driving IC D-IC is disposed in the COP manner, but it is not limited thereto.

At this time, as the substrate 110 is bent, the driving IC D-IC disposed in the second non-active area NA2 can be disposed below the active area AA. For example, the driving IC D-IC and the printed circuit board connected to the pad unit of the substrate 110 move to the rear surface of the substrate 110 and overlap the active area AA. Therefore, as seen from the top of the substrate 110, circuit elements, such as the driving IC D-IC and the printed circuit board may not be visible. Accordingly, a size of the non-active area which is visible from the top of the substrate 110 is reduced to implement a narrow bezel. A cover layer CL is disposed in the active area AA, a first non-active area NA1, and a second non-active area NA2 on the substrate 110. The cover layer CL may not be disposed in the bending area BA on the substrate 110. The cover layer CL can protect components therebelow from various chemicals and foreign materials during a manufacturing process.

The cover layer CL can be formed of an inorganic insulating material. For example, the cover layer CL can be formed of an inorganic insulating material, such as silicon nitride (SiNx) or silicon oxide (SiOx), but it is not limited thereto.

The cover layer CL includes a first cover layer CL1 and a second cover layer CL2.

The first cover layer CL1 is disposed in the active area AA and the first non-active area NA1. The first cover layer CL1 is disposed to extend from the active area AA to the first non-active area NA1.

The second cover layer CL2 is disposed in the second non-active area NA2. The second cover layer CL2 is disposed on the same layer as the first cover layer CL1 with the same material as the first cover layer CL1.

The first cover layer CL1 and the second cover layer CL2 can be spaced apart from each other with the bending area BA therebetween. For example, the cover layer CL is configured so as not to be disposed in the bending area BA. For example, the cover layer CL can be configured to minimize a thickness of the bending area BA, but is not limited thereto.

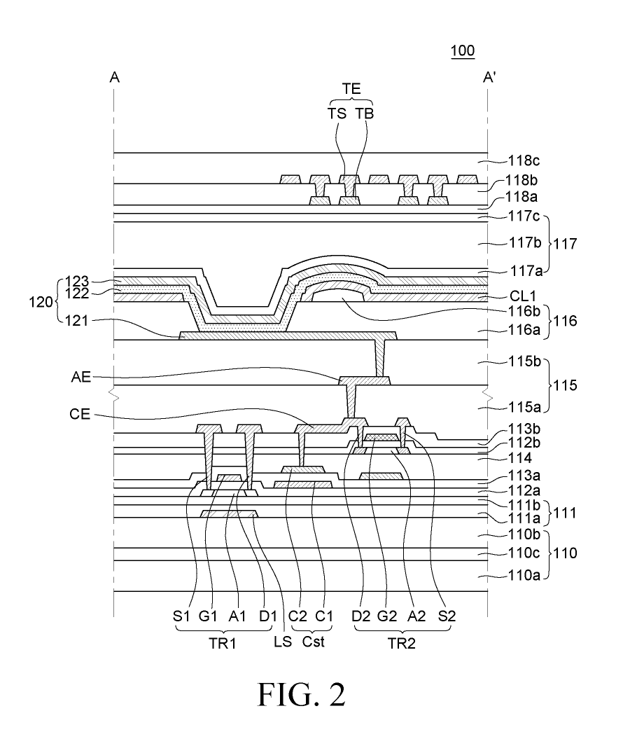

Hereinafter, a cross-sectional structure of the active area AA will be described with reference to FIG. 2 together.

FIG. 2 is a cross-sectional view taken along line A-A' of FIG. 1 according to an example of the present disclosure. For example, FIG. 2 is a cross-sectional view illustrating a cross-sectional structure of one sub pixel SP disposed in an active area AA according to an example embodiment of the present disclosure.

Referring to FIG. 2, in the display apparatus 100 according to the example embodiment of the present disclosure, in the active area AA, a substrate 110, a light shielding layer LS, a first buffer layer 111, a first thin film transistor TR1, a second thin film transistor TR2, a first gate insulating layer 112a, a first interlayer insulating layer 113a, a second buffer layer 114, a second gate insulating layer 112b, a second interlayer insulating layer 113b, a connection electrode CE, a first planarization layer 115a, a second planarization layer 115b, an auxiliary electrode AE, a bank 116a, a spacer 116b, a light emitting diode 120, a first cover layer CL1, an encapsulation unit 117, and a touch sensing unit are disposed.

The substrate 110 serves to support and protect components of the display apparatus 100 disposed thereabove.

The substrate 110 is a configuration for supporting various components included in the display apparatus 100 and can be formed of an insulating material. In the meantime, the substrate 110 is disposed so as to support components on the lowermost portion of the display apparatus 100 so that the substrate is also referred to as a lower substrate, but is not limited thereto.

The substrate 110 can include a first substrate 110a, a second substrate 110b, and an interlayer insulating film 110c. The interlayer insulating film 110c can be disposed between the first substrate 110a and the second substrate 110b. As described above, the substrate 110 is configured by the first substrate 110a, the second substrate 110b, and the interlayer insulating film 110c to suppress the moisture permeation. However, the substrate 110 can be disposed as a single layer, but is not limited thereto.

For example, the first substrate 110a and the second substrate 110b can be polyimide (PI) substrates and the interlayer insulating film 110c can be formed of a single layer of silicon nitride (SiNx) or silicon oxide (SiOx) or multiple layers thereof.

The interlayer insulating film 110c may not be disposed in at least a partial area. For example, the interlayer insulating film 110c may not be formed in an area to which a stress is concentrated, such as a bending area BA or an outermost area.

The light shielding layer LS can be disposed on the substrate 110. The light shielding layer LS is a protection layer formed of metal which is disposed below semiconductor layers A1 and A2 of a plurality of transistors TR1 and TR2 to shield external light in the display apparatus 100. The light shielding layer LS can prevent or minimize damage of the semiconductor layers A1 and A2 which can be caused by the external light.

The first buffer layer 111 can be disposed on the substrate 110 while covering the light shielding layer LS. Specifically, a multi-buffer layer 111a is disposed on the substrate 110 while covering the light shielding layer LS and an active buffer layer 111b can be disposed on the multi-buffer layer 111a.

The multi-buffer layer 111a can delay diffusion of the moisture or oxygen permeating the substrate 110 and can include at least any one of silicon nitride (SiNx) and silicon oxide (SiOx).

The active buffer layer 111b protects the first semiconductor layer A1 and can block various types of defects introduced from the substrate 110. For example, the active buffer layer 111b can include at least any one of amorphous silicon (a-Si), silicon nitride (SiNx), and silicon oxide (SiOx).

The first thin film transistor TR1 can be disposed on the first buffer layer 111. The first thin film transistor TR1 can include the first semiconductor layer A1, a first gate electrode G1, a first source electrode S1, and a first drain electrode D1. Here, depending on the design of the pixel circuit, the first source electrode S1 can serve as a first drain electrode and the first drain electrode D1 can serve as a first source electrode.

The first semiconductor layer A1 can be disposed on the first buffer layer 111 so as to overlap the light shielding layer LS. The first semiconductor layer A1 can include amorphous silicon or polycrystalline silicon. For example, the first semiconductor layer A1 can include a low-temperature polycrystalline silicon LTPS. For example, the polycrystalline silicon material has a high mobility (100 cm²/Vs or higher) so that energy power consumption is low and reliability is excellent. Therefore, the polysilicon material can be applied to a gate driver for driving elements which drive thin film transistors for a display element and/or a multiplexer (MUX) and also applied as a first semiconductor layer A1 of a driving thin film transistor of the display apparatus 100 according to the example embodiment, but is not limited thereto. For example, the polycrystalline silicon material can also be applied as a second semiconductor layer A2 of the switching thin film transistor according to the characteristic of the display apparatus 100. An amorphous silicon (a-Si) material is deposited on the first buffer layer 111 and a dehydrogenation process and a crystallization process are performed to form polycrystalline silicon and the polycrystalline silicon is patterned to form the first semiconductor layer A1.

Here, the first semiconductor layer A1 can include a first channel region in which a channel is formed when the first thin film transistor TR1 is driven and a first source region and a first drain region on both sides of the first channel region. The first source region refers to a part of the first semiconductor layer A1 which is connected to the first source electrode S1 and the first drain region refers to a part of the first semiconductor layer A1 which is connected to the first drain electrode D1. For example, the first source region and the first drain region are configured by ion-doping (impurity doping) of the first semiconductor layer A1. The first source region and the first drain region can be generated by doping ions into the polysilicon material and the first channel region can refer to a part which is not doped with ions, but remains as the polysilicon material.

The first gate insulating layer 112a can be disposed on the first semiconductor layer A1. The first gate insulating layer 112a can be configured by a single layer of silicon nitride (SiNx) or silicon oxide (SiOx) or a multi-layer thereof. In the first gate insulating layer 112a, a contact hole through which the first source electrode S1 and the first drain electrode D1 of the first thin film transistor TR1 are connected to the first source region and the first drain region of the first semiconductor layer A1 of the first thin film transistor TR1, respectively, can be formed.

The first gate electrode G1 of the first thin film transistor TR1 and a first capacitor electrode C1 of the storage capacitor Cst can be disposed on the first gate insulating layer 112a.

At this time, the first gate electrode G1 and the first capacitor electrode C1 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The first gate electrode G1 can be formed on the first gate insulating layer 112a so as to overlap the first channel region of the first semiconductor layer A1 of the first thin film transistor TR1.

The first capacitor electrode C1 can be omitted based on a driving characteristic of the display apparatus 100 and a structure and a type of the thin film transistor. The first gate electrode G1 and the first capacitor electrode C1 can be formed by the same process. Further, the first gate electrode G1 and the first capacitor electrode C1 can be formed of the same material on the same layer.

The first interlayer insulating layer 113a can be disposed above the first gate insulating layer 112a, the first gate electrode G1, and the first capacitor electrode C1. The first interlayer insulating layer 113a can be configured by a single layer of silicon nitride (SiNx) or silicon oxide (SiOx) or a multi-layer thereof. Further, in the first interlayer insulating layer 113a, a contact hole for exposing the first source region and the first drain region of the first semiconductor layer A1 of the first thin film transistor TR1 can be formed.

A second capacitor electrode C2 of the storage capacitor Cst can be disposed on the first interlayer insulating layer 113a. The second capacitor electrode C2 can be formed by a single layer or a multiple layer formed of any one of molybdenum (Mo), copper (Cu), titanium (Ti), aluminum (Al), chrome (Cr), gold (Au), nickel (Ni), and neodymium (Nd) or an alloy thereof. The second capacitor electrode C2 can be formed on the first interlayer insulating layer 113a so as to overlap the first capacitor electrode C1. Further, the second capacitor electrode C2 can be formed of the same material as the first capacitor electrode C1. The second capacitor electrode C2 can be omitted based on a driving characteristic of the display apparatus 100 and a structure and a type of the thin film transistor.

The second buffer layer 114 can be disposed on the first interlayer insulating layer 113a and the second capacitor electrode C2. The second buffer layer 114 can be configured by a single layer of silicon nitride (SiNx) or silicon oxide (SiOx) or a multi-layer thereof. A contact hole for exposing the first source region and the first drain region of the first semiconductor layer A1 of the first thin film transistor TR1 can be formed in the second buffer layer 114. Further, in the second buffer layer 114, a contact hole for exposing the second capacitor electrode C2 of the storage capacitor Cst can be formed.

The second buffer layer 114 can be formed by a multiple layer, but is not limited thereto.

The second semiconductor layer A2 of the second thin film transistor TR2 can be disposed on the second buffer layer 114. Here, the second thin film transistor TR2 can include the second semiconductor layer A2, a second gate insulating layer 112b, a second gate electrode G2, a second source electrode S2, and a second drain electrode D2. Here, depending on the design of the pixel circuit, the second source electrode S2 can serve as a drain electrode and the second drain electrode D2 can serve as a source electrode.

Further, the second semiconductor layer A2 can include a second channel region in which a channel is formed when the second thin film transistor TR2 is driven and a second source region and a second drain region on both sides of the second channel region. The second source region can refer to a part of the second semiconductor layer A2 which is connected to the second source electrode S2 and the second drain region can refer to a part of the second semiconductor layer A2 which is connected to the second drain electrode D2.

The second semiconductor layer A2 can be formed of an oxide semiconductor. The oxide semiconductor material has a larger band gap than a silicon material so that electrons may not jump over the band gap in an off state. Therefore, the oxide semiconductor material has a small off-current. Therefore, the thin film transistor including a semiconductor layer which is formed of an oxide semiconductor is suitable for a switching thin film transistor which maintains on-time to be short and off-time to be long, but is not limited thereto.

Depending on the characteristic of the display apparatus 100, a thin film transistor including a semiconductor layer formed of oxide semiconductor can be applied as a driving thin film transistor. Further, due to the small off-current, a magnitude of an auxiliary capacitance can be reduced so that the oxide semiconductor can be appropriate for a high resolution display element. For example, the second semiconductor layer A2 can be formed of metal oxide and for example, can be formed of various metal oxide such as indium-gallium-zinc-oxide (IGZO). Here, the description was made under assumption that the second semiconductor layer A2 of the second thin film transistor TR2 is configured by IGZO, among various metal oxides, but it is not limited thereto. Therefore, the second semiconductor layer A2 of the second thin film transistor TR2 can be formed of another metal oxide such as indium-zinc-oxide (IZO), indium-gallium-tin-oxide (IGTO), or indium-gallium-oxide (IGO), in addition to IGZO.

The second semiconductor layer A2 can be formed by depositing the metal oxide on the second buffer layer 114, performing a heat treatment for stabilization, and then patterning the metal oxide.

The second gate insulating layer 112b can be disposed on the entire substrate 110 including the second semiconductor layer A2. For example, the second gate insulating layer 112b can be configured by a single layer of silicon nitride (SiNx) or silicon oxide (SiOx) or a multi-layer thereof.

The second gate electrode G2 can be disposed on the second gate insulating layer 112b.

The second gate electrode G2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof.

For example, a metal material is formed on the second gate insulating layer 112b, a photoresist pattern is formed on the metal material, and then the metal material is wet-etched using the photoresist pattern as a mask to form the second gate electrode G2. As a wet etchant for etching the metal material, a material which selectively etches molybdenum (Mo), copper (Cu), titanium (Ti), aluminum (Al), chrome (Cr), gold (Au), nickel (Ni), and neodymium (Nd) or an alloy thereof which configures the metal material but does not etch the insulating material can be used.

The second interlayer insulating layer 113b can be disposed on the second gate insulating layer 112b and the second gate electrode G2. A contact hole for exposing the first semiconductor layer A1 of the first thin film transistor TR1 and the second semiconductor layer A2 of the second thin film transistor TR2 can be formed in the second interlayer insulating layer 113b. For example, a contact hole for exposing the first source region and the first drain region of the first semiconductor layer A1 of the first thin film transistor TR1 can be formed in the second interlayer insulating layer 113b. A contact hole for exposing the second source region and the second drain region of the second semiconductor layer A2 of the second thin film transistor TR2 can be formed in the second interlayer insulating layer 113b.

The second interlayer insulating layer 113b can be configured as a single layer of silicon nitride (SiNx) or silicon oxide (SiOx) or a multi-layer thereof.

The connection electrode CE, the first source electrode S1 and the first drain electrode D1 of the first thin film transistor TR1 and the second source electrode S2 and the second drain electrode D2 of the second thin film transistor TR2 can be disposed on the second interlayer insulating layer 113b.

The connection electrode CE can be electrically connected to the second drain electrode D2 of the second thin film transistor TR2. Further, the connection electrode CE can be electrically connected to the second capacitor electrode C2 of the storage capacitor Cst through the contact holes formed in the second buffer layer 114 and the second interlayer insulating layer 113b. For example, the connection electrode CE can serve to electrically connect the second capacitor electrode C2 of the storage capacitor Cst and the second drain electrode D2 of the second thin film transistor TR2 to each other.

Here, the first source electrode S1 and the first drain electrode D1 of the first thin film transistor TR1 can be connected to the first semiconductor layer A1 of the first thin film transistor TR1 through the contact holes formed in the first gate insulating layer 112a, the first interlayer insulating layer 113a, the second buffer layer 114, and the second interlayer insulating layer 113b.

The second source electrode S2 and the second drain electrode D2 of the second thin film transistor TR2 can be connected to the second semiconductor layer A2 through the contact hole formed in the second interlayer insulating layer 113b.

The connection electrode CE, the first source electrode S1 and the first drain electrode D1 of the first thin film transistor TR1 and the second source electrode S2 and the second drain electrode D2 of the second thin film transistor TR2 can be formed of the same material by the same process.

For example, the connection electrode CE, the first source electrode S1 and the first drain electrode D1 of the first thin film transistor TR1 and the second source electrode S2 and the second drain electrode D2 of the second thin film transistor TR2 can be formed by a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. For example, the connection electrode CE, the first source electrode S1 and the first drain electrode D1 of the first thin film transistor TR1 and the second source electrode S2 and the second drain electrode D2 of the second thin film transistor TR2 can be formed of a triple layered structure of titanium (Ti)/aluminum (Al)/titanium (Ti), but are not limited thereto.

The connection electrode CE can be integrally formed to be connected to the second drain electrode D2 of the second thin film transistor TR2, but is not limited thereto.

The first planarization layer 115a can be disposed on the connection electrode CE, the first source electrode S1 and the first drain electrode D1 of the first thin film transistor TR1, the second source electrode S2 and the second drain electrode D2 of the second thin film transistor TR2, and the second interlayer insulating layer 113b.

The first planarization layer 115a can be an organic insulating layer which planarizes and protects upper portions of the first thin film transistor TR1 and the second thin film transistor TR2. For example, the first planarization layer 115a can be formed of an organic material such as acryl resin, epoxy resin, phenolic resin, polyamide resin, or polyimide resin.

The auxiliary electrode AE can be disposed on the first planarization layer 115a. The auxiliary electrode AE can be connected to the second drain electrode D2 of the second thin film transistor TR2 through the contact hole of the first planarization layer 115a. The auxiliary electrode AE can serve to electrically connect the second thin film transistor TR2 and the first electrode 121 with each other. Further, the auxiliary electrode AE can be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof. The auxiliary electrode AE can be formed of the same material as the second source electrode S2 and the second drain electrode D2 of the second thin film transistor TR2.

The second planarization layer 115b can be disposed above the auxiliary electrode AE and the first planarization layer 115a. For example, the second planarization layer 115b can be formed of an organic material, such as acryl resin, epoxy resin, phenolic resin, polyamide resin, or polyimide resin. The first planarization layer 115a and the second planarization layer 115b can be collectively referred to as a planarization layer 115.

The light emitting diode 120 can be disposed on the second planarization layer 115b. The light emitting diode 120 includes an anode 121, an organic layer 122, and a cathode 123.

The anode 121 can be disposed on the second planarization layer 115b. At this time, the anode 121 can be electrically connected to the auxiliary electrode AE through the contact hole provided in the second planarization layer 115b. The anode 121 can be formed of a metallic material.

When the display apparatus 100 is a top emission type in which light emitted from the light emitting diode 120 is emitted above the substrate 110 on which the light emitting diode 120 is disposed, the anode 121 can include a reflective layer and a transparent conductive layer disposed on the reflective layer. The transparent conductive layer can be formed of transparent conductive oxide such as indium tin oxide (ITO) or indium zinc oxide (IZO) and for example, the reflective layer can be formed of silver (Ag), aluminum (Al), gold (Au), molybdenum (Mo), tungsten (W), chrome (Cr), or an alloy thereof, but they are not limited thereto.

The bank unit 116 is disposed on the anode 121. The bank unit 116 includes a bank 116a and a spacer 116b.

The bank 116a can be disposed while covering an end of the anode 121. A part of the bank 116a corresponding to an emission area of the sub pixel can be open. A part of the anode 121 can be exposed through the open part of the bank 116a (hereinafter, referred to as an open area). At this time, the bank 116a can be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

The spacer 116b can be further disposed on the bank 116a. The spacer 116b can serve to maintain a predetermined gap so as not to allow a mask to be in contact with a substrate during a manufacturing process of the organic layer 122 of the light emitting diode 120 which is formed of an organic material.

For example, the spacer 116b can be formed of an inorganic insulating material, such as silicon nitride (SiNx) or silicon oxide (SiOx), or an organic insulating material, such as benzocyclobutene-based resin, acrylic-based resin or imide-based resin, but is not limited thereto.

The first cover layer CL1 is disposed on the bank 116a and the spacer 116b. The first cover layer CL1 is disposed between the bank 116a and the spacer 116b and the organic layer 122. At this time, the first cover layer CL1 is disposed so as not to overlap the anode 121 exposed from the bank 116a. For example, the first cover layer CL1 is disposed so as not to overlap the emission area of the light emitting diode 120 defined by the bank 116a. Therefore, the first cover layer CL1 can be configured so as not to limit the emission area of the light emitting diode 120.

The first cover layer CL1 can be formed of an inorganic insulating material. For example, the cover layer CL can be formed of an inorganic insulating material, such as silicon nitride (SiNx) or silicon oxide (SiOx), but is not limited thereto.

For example, the first cover layer CL1 can be disposed on the bank 116a and the spacer 116b, after forming the bank 116a and the spacer 116b in the manufacturing process of the light emitting diode 120. Further, after placing the first cover layer CL1, the organic layer 122 can be disposed on the first cover layer CL1. Therefore, the first cover layer CL1 can be configured so as to protect components disposed below the first cover layer CL1, such as a plurality of transistors TR1 and TR2, during a manufacturing process of the organic layer 122 which is formed by a plurality of layers, from foreign materials or damage generated during the manufacturing process of the organic layer 122.

The organic layer 122 is disposed on the anode 121, the bank 116a, the spacer 116b, and the first cover layer CL1. The organic layer 122 can be disposed in the open area of the bank 116a and in the vicinity of the open area of the bank. Therefore, the organic layer 122 can be disposed on the anode 121 exposed through the open area of the bank 116a.

The organic layer 122 can include a plurality of organic material layers. For example, the organic layer 122 can include an organic material layer such as an emission layer, a hole injection layer, a hole transport layer, an electron transport layer, and an electron injection layer. In the meantime, when the organic layer 122 includes the emission layer that emits white light, light emitted from the organic layer 122 can be converted into light with various colors by a plurality of color filters CF, but is not limited thereto.

The cathode 123 is disposed on the organic layer 122. The cathode 123 supplies electrons to the organic layer 122, and thus the cathode can be formed of a conductive material having a low work function. The cathode 123 can be formed as one layer over the plurality of sub pixels SP. For example, the cathodes 123 of the plurality of sub pixels SP are connected to be integrally formed.

For example, the cathode 123 can be formed of a transparent conductive material such as indium tin oxide (ITO) and indium zinc oxide (IZO) or ytterbium (Yb) alloy and can further include a metal doping layer, but is not limited thereto.

The encapsulation unit 117 is disposed on the light emitting diode 120.

The encapsulation unit 117 can have a single layer structure or a multi-layered structure. For example, the encapsulation unit 117 can have a multi-layered structure including a first encapsulation layer 117a, a second encapsulation layer 117b, and a third encapsulation layer 117c. However, the encapsulation unit can also be formed with a single layer structure, but is not limited thereto.

The first encapsulation layer 117a and the third encapsulation layer 117c are formed of inorganic materials and the second encapsulation layer 117b can be formed of an organic material. Accordingly, the first encapsulation layer 117a and the third encapsulation layer 117c can be referred to as an inorganic encapsulation layer, and the second encapsulation layer 117b can be referred to as an organic encapsulation layer. The second encapsulation layer 117b can be the thickest among the first encapsulation layer 117a, the second encapsulation layer 117b, and the third encapsulation layer 117c. The second encapsulation layer 117b can planarize an upper portion of the light emitting diode 120.

The first encapsulation layer 117a is disposed on the cathode 123 and is disposed to be most adjacent to the light emitting diode 120, in the encapsulation unit 117. For example, the first encapsulation layer 117a can be configured by silicon nitride (SiNx), silicon oxide (SiOx), silicon oxynitride (SiON), or aluminum oxide (Al2O3), but is not limited thereto.

The second encapsulation layer 117b can be formed to have a smaller area than that of the first encapsulation layer 117a. In this case, the second encapsulation layer 117b can be formed to expose both ends of the first encapsulation layer 117a. The second encapsulation layer 117b can serve to enhance a buffering function to alleviate stress between the layers due to bending of the flexible display apparatus and a planarization function.

For example, the second encapsulation layer 117b can be formed of an organic insulating material, such as acrylic resin, epoxy resin, polyimide, polyethylene, or silicon oxy carbon (SiOC). For example, the second encapsulation layer 117b can be formed by an inkjet method, but is not limited thereto.

The third encapsulation layer 117c can be formed above the substrate 110 on which the second encapsulation layer 117b is formed so as to cover upper surfaces and side surfaces of the second encapsulation layer 117b and the first encapsulation layer 117a. At this time, the third encapsulation layer 117c can minimize or block the permeation of external moisture or oxygen into the first encapsulation layer 117a and the second encapsulation layer 117b. For example, the third encapsulation layer 117c can be configured by an inorganic insulating material, such as silicon nitride (SiNx), silicon oxide (SiOx), silicon oxynitride (SiON), or aluminum oxide (Al₂O₃), but is not limited thereto.

The touch buffer layer 118a can be disposed on the encapsulation unit 117, and the touch sensing unit can be disposed on the touch buffer layer 118a .

The touch sensing unit includes a touch interlayer insulating layer 118b, a touch electrode TE, and a touch insulating layer 118c. The touch electrode TE can include a touch sensor electrode TS and a touch bridge electrode TB located on different layers.

The touch buffer layer 118a is disposed on the third encapsulation layer 117c. The touch buffer layer 118a can be formed of an inorganic insulating material, such as silicon oxide (SiOx) or silicon nitride (SiNx). The touch buffer layer 118a can be formed by laminating a plurality of insulating layers, but is not limited thereto.

The touch bridge electrode TB can be disposed on the touch buffer layer 118a. The touch bridge electrode TB is disposed on a different layer from the touch sensor electrode TS to connect the plurality of touch sensor electrodes TS.

The touch interlayer insulating layer 118b is disposed on the touch bridge electrode TB. For example, the touch interlayer insulating layer 118b can be formed of an inorganic insulating material or an organic insulating material. Therefore, the touch interlayer insulating layer 118b can minimize a step in a location where the touch electrode TE is disposed and electrically insulate the touch sensor electrode TS from the touch bridge electrode TB.

The touch sensor electrode TS can be disposed on the touch interlayer insulating layer 118b. The touch sensor electrode TS is a configuration which senses a touch input of the user. The plurality of touch sensor electrode TS can be disposed to be spaced apart from each other in the active area AA.

The touch insulating layer 118c is disposed on the touch sensor electrode TS. The touch insulating layer 118c can be an organic insulating layer which planarizes and protects an upper portion of the touch sensor electrode TS. Therefore, the touch insulating layer 118c can be disposed to be in contact with the touch sensor electrode TS. For example, the touch insulating layer 118c can be formed of an organic material, such as acryl resin, epoxy resin, phenolic resin, polyamide resin, or polyimide resin, but is not limited thereto.

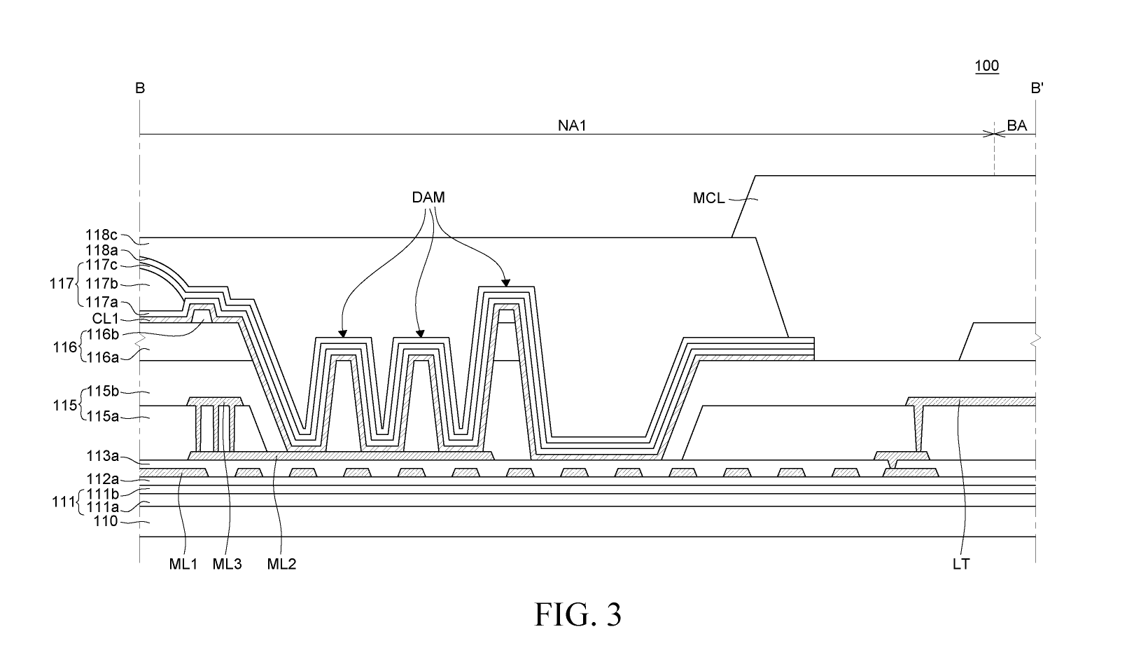

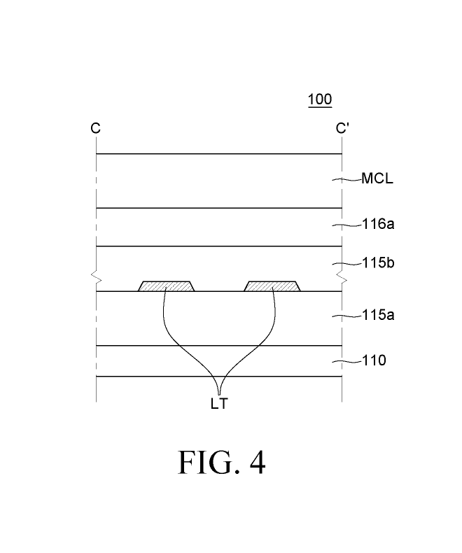

Hereinafter, a cross-sectional structure of the first non-active area NA1 and the bending area BA will be described with reference to FIGS. 3 and 4 together.

FIG. 3 is a cross-sectional view taken along line B-B' of FIG. 1 according to an example of the present disclosure. FIG. 4 is a cross-sectional view taken along line C-C' of FIG. 1 according to an example of the present disclosure. For example, FIG. 3 is a cross-sectional view illustrating a cross-sectional structure of the first non-active area NA1 and a part of the bending area BA and FIG. 4 is a cross-sectional view illustrating a cross-sectional structure of the bending area BA.

Referring to FIGS. 3 and 4, in the display apparatus 100 according to the example embodiment of the present disclosure, in the first non-active area NA1, a first metal layer ML1, a second metal layer ML2, a third metal layer ML3, a plurality of dams DAM, a first cover layer CL1, an encapsulation unit 117, a touch buffer layer 118a, and a touch insulating layer 118c are disposed. In the bending area BA, a routing line LT and a micro coating layer MCL are disposed. The micro coating layer MCL can be a protective layer formed of, for example, an acrylic resin, but is not limited thereto.

In the first non-active area NA1 and a part of the bending area BA, the first metal layer ML1 is disposed on the first gate insulating layer 112a. The first metal layer ML1 can be, for example, a power line for transmitting a low potential power voltage or a high potential power voltage to the active area AA, but is not limited thereto. The first metal layer ML1 can be formed of the same material as one of various conductive components formed in the active area AA. For example, the first metal layer ML1 can be formed on the first gate insulating layer 112a by the same process and with the same material as the first gate electrode G1 or the second gate electrode G2, but the present disclosure is not limited thereto.

Referring to FIG. 3, the first metal layer ML1 can include a plurality of holes. Therefore, gas which is generated from the first gate insulating layer 112a or the first interlayer insulating layer 113a during the manufacturing process is easily discharged to the outside through the plurality of holes of the first metal layer ML1.

The second metal layer ML2 is disposed on the first interlayer insulating layer 113a. The second metal layer ML2 can be formed of the same material as one of various conductive components formed in the active area AA. For example, the second metal layer ML2 can be formed on the first interlayer insulating layer 113a by the same process and with the same material as the source electrodes S1 and S2 and the drain electrodes D1 and D2, but the present disclosure is not limited thereto.

For example, the second metal layer ML2 can be a low potential power line. The second metal layer ML2 can be electrically connected to the cathode 123 through the third metal layer ML3. Therefore, the second metal layer ML2 can supply a low potential voltage to the cathode 123.

The third metal layer ML3 is disposed on the second metal layer ML2 and the first planarization layer 115a. The third metal layer ML3 can be formed of the same material as one of various conductive components formed in the active area AA. For example, the third metal layer ML3 can be formed of the same material by the same process as the auxiliary electrode AE on the first planarization layer 115a, but the present disclosure is not limited thereto.

Referring to FIGS. 3 and 4, the routing line LT is disposed in the first non-active area NA1 and the bending area BA. For example, the routing line LT is disposed on the first planarization layer 115a and can be electrically connected to the first metal layer ML1 through a contact hole. The routing line LT is connected to various lines or electrodes disposed in the active area AA to transmit various signals from the second non-active area NA2 to the active area AA through the bending area BA.

In the first non-active area NA1, a plurality of dams DAM is disposed in an area adjacent to an end of the substrate 110. The plurality of dams DAM is disposed so as to enclose the active area AA in the first non-active area NA1.

The plurality of dams DAM can be disposed so as to overlap the first metal layer ML1 and the second metal layer ML2, but is not limited thereto. The plurality of dams DAM is disposed to be adjacent to the active area AA to suppress excessive application of the second encapsulation layer 117b.

The plurality of dams DAM can have a structure in which a plurality of organic insulating layers formed by the same material as components disposed in the active area AA is laminated. For example, each of the plurality of dams DAM can be formed by the same process with the same material as at least any one of the second planarization layer 115b, the bank 116a, and the spacer 116b, but is not limited thereto.

Further, even though in FIG. 3, it is illustrated that the plurality of dams DAM is configured by three, it is not limited thereto and the number of the plurality of dams DAM can be changed if necessary.

The first cover layer CL1 is disposed to extend from the active area AA to the first non-active area NA1. The first cover layer CL1 is disposed on the plurality of dams DAM in the first non-active area NA1. The first cover layer CL1 is disposed so as to cover the plurality of dams DAM. For example, the first cover layer CL1 is in contact with top surfaces of the plurality of dams DAM and can be disposed along the top surfaces of the plurality of dams DAM.

Referring to FIG. 3, the first encapsulation layer 117a, the third encapsulation layer 117c, and the touch buffer layer 118a can be disposed above the first cover layer CL1. The first cover layer CL1 and the first encapsulation layer 117a can be disposed to be in contact with each other. Further, ends of the first cover layer CL1, the first encapsulation layer 117a, the third encapsulation layer 117c, and the touch buffer layer 118a can be disposed on the same plane (for example, these ends can be disposed on the same vertical plane, or these ends can be vertically flush, e.g., aligned with each other). For example, the first cover layer CL1, the first encapsulation layer 117a, the third encapsulation layer 117c, and the touch buffer layer 118a can be patterned by the same process, but the present disclosure is not limited thereto.

In the meantime, in the display apparatus 100 according to the example embodiment of the present disclosure, the first cover layer CL1 is formed using the same material as inorganic insulating material of a plurality of insulating layers included in the touch buffer layer 118a. The touch buffer layer 118a can be configured so as to exclude any one of the plurality of insulating layers included in conventional touch buffer layer. Accordingly, the first cover layer CL1 can be configured as if any one inorganic insulating layer included in the touch buffer layer 118a moves to a layer in the vicinity of the light emitting diode 120. Therefore, even though the first cover layer CL1 is disposed on a layer in the vicinity of the light emitting diode 120, the number or a thickness of insulating layers between the plurality of transistors TR1 and TR2 and the touch sensing unit disposed in the active area AA can be configured to be maintained to be the same. For example, the first cover layer CL1 can be formed of the same material as the touch buffer layer 118a and can be formed using the same mask, but is not limited thereto.

In the first non-active area NA1, the touch insulating layer 118c is disposed on the touch buffer layer 118a. The touch insulating layer 118c can be configured to planarize upper portions of the components disposed in the first non-active area NA1.

The micro coating layer MCL is disposed in the first non-active area NA1 and the bending area BA. The micro coating layer MCL can be disposed so as to cover the end of the touch insulating layer 118c in the first non-active area NA1. The micro coating layer MCL can be disposed on the uppermost layer in the bending area BA. Therefore, when the substrate 110 is bent, the micro coating layer MCL can be configured so as to protect components disposed therebelow in the bending area BA. An end of the first cover layer CL1 can be disposed so as to overlap the micro coating layer MCL, but is not limited thereto.

During the manufacturing process of a display apparatus, as various components are deposited and patterned, foreign materials occur or damages can be caused due to various chemicals. Specifically, during a process of placing a component which is formed by a plurality of layers, such as an organic emission layer of the light emitting diode and an encapsulation unit, more foreign materials or damages can be generated. There can be problems in that moisture permeates the display apparatus due to the foreign materials or damages as described above and the reliability and the display quality of the display apparatus can be degraded.

In the meantime, in the display apparatus including a bending area to implement a narrow bezel, the placement of the inorganic insulating layer is minimized to suppress or minimize the cracks and reduce the thickness of a portion adjacent to the bending area. However, in the portion adjacent to the bending area, when the foreign materials or damages are generated, the insulating layer is not sufficient to cover an upper portion of a damaged portion by the foreign material or the damage so that the portion adjacent to the bending area can serve as an area which is vulnerable to the moisture permeation.

In the display apparatus 100 according to the example embodiment of the present disclosure, the cover layer CL is disposed in the active area AA and the first non-active area NA1 adjacent to the bending area BA. Therefore, the moisture permeation defect of the active area AA and the first non-active area NA1 adjacent to the bending area BA can be minimized or prevented.

Specifically, in the display apparatus 100 according to the example embodiment of the present disclosure, in the active area AA and the first non-active area NA1 adjacent to the bending area BA, the first cover layer CL1 of the cover layer CL is disposed. The first cover layer CL1 is disposed to extend from the active area AA to the first non-active area NA1. The first cover layer CL1 is disposed above the bank 116a and the spacer 116b in the active area AA and is disposed on the plurality of dams DAM in the first non-active area NA1. For example, the first cover layer CL1 can cover upper portions of the plurality of transistors TR1 and TR2 in the active area AA and can cover upper portions of the plurality of dams DAM in the first non-active area NA1. Therefore, the first cover layer CL1 can be configured to protect components therebelow from various chemicals and foreign materials during a manufacturing process of the organic layer 122 and the encapsulation unit 117 which are formed by a plurality of layers. Therefore, moisture permeation which can be caused to components disposed below the first cover layer CL1, for example, the plurality of transistors TR1 and TR2 of the active area AA and the plurality of dams DAM of the first non-active area NA1 due to the foreign materials and damages can be minimized or prevented. Accordingly, in the display apparatus 100 according to the example embodiment of the present disclosure, the cover layer CL is disposed in the active area AA and the first non-active area NA1 adjacent to the bending area BA. Therefore, the moisture permeation defect of the active area AA and the first non-active area NA1 adjacent to the bending area BA can be minimized or prevented and the display quality and the reliability of the display apparatus 100 can be improved.

In the meantime, in the display apparatus 100 according to the example embodiment of the present disclosure, a process of forming the cover layer CL is performed together with the manufacturing process of the light emitting diode 120 to minimize a margin distance needed to form the cover layer CL.

Specifically, in the display apparatus 100 according to the example embodiment of the present disclosure, the first cover layer CL1 is disposed between the bank 116a and the spacer 116b and the organic layer 122 in the active area AA. For example, the process of forming the cover layer CL can be performed together in the process of manufacturing the plurality of light emitting diodes 120. At this time, the processing method used for the process of manufacturing the plurality of light emitting diode 120 can use a processing method with a relatively improved precision as compared with the processing method of forming the encapsulation unit 117 and the touch sensing unit disposed above the plurality of light emitting diodes 120. When the process of forming the cover layer CL is performed together in the process of manufacturing the plurality of light emitting diodes 120, a margin distance needed for the cover layer CL to stably cover the upper portion of the plurality of dams DAM can be minimized. Accordingly, in the display apparatus 100 according to the example embodiment of the present disclosure, a process of forming the cover layer CL is performed together in the manufacturing process of the light emitting diode 120 to minimize a margin distance needed to form the cover layer CL and implement the display apparatus 100 with a narrow bezel.

The example embodiments of the present disclosure can also be described as follows:

According to an aspect of the present disclosure, a display apparatus includes a substrate which includes an active area, a first non-active area enclosing the active area, a bending area extending from the first non-active area to be bent, and a second non-active area extending from the bending area; a plurality of light emitting diodes which is disposed in the active area on the substrate and each includes an anode, an organic layer, and a cathode; a bank which is disposed so as to cover an end of the anode; and a cover layer which is disposed on the bank and is disposed to extend from the active area to the first non-active area, and the organic layer is disposed so as to cover the cover layer on the bank.

The cover layer can be disposed so as not to overlap the anode which is exposed from the bank.

The display apparatus can further comprise a plurality of dams which is disposed so as to enclose the active area in the first non-active area.

The cover layer can extend from the active area to cover the plurality of dams.

The display apparatus can further comprise an encapsulation unit which includes a plurality of inorganic encapsulation layers and an organic encapsulation layer.

The organic encapsulation layer can be disposed not to extend to the plurality of dams, the plurality of inorganic encapsulation layers can be disposed so as to cover the plurality of dams and the cover layer, and the cover layer and the plurality of inorganic encapsulation layers can be in contact with each other.

Ends of the cover layer and the plurality of inorganic encapsulation layers can be disposed on the same plane.

The cover layer can include a first cover layer which is disposed in the active area and the first non-active area, and a second cover layer which is disposed in the second non-active area and is formed of the same material as the first cover layer.

The first cover layer and the second cover layer can be spaced apart from each other with the bending area therebetween.

The display apparatus can further comprise an encapsulation unit including a plurality of inorganic encapsulation layers and an organic encapsulation layer, a planarization layer on which the plurality of light emitting diodes is disposed, and a micro coating layer which extends from an end of the first non-active area to ends of the bending area and the second non-active area and a portion of which is disposed on the planarization layer in the first non-active area.

An end of the cover layer can be disposed so as to overlap the micro coating layer.

The display apparatus can further comprise a touch sensing unit disposed on the encapsulation unit in the active area, and a touch buffer layer disposed between the encapsulation unit and the touch sensing unit.

In the first non-active area, the end of the cover layer can be disposed on the same plane as an end of the touch buffer layer.

The cover layer can be formed of an inorganic insulating material.

The display apparatus can further comprise a spacer disposed on the bank, and the cover layer can also be disposed on the spacer.

The cover layer can be formed of the same material as the touch buffer layer, and the cover layer and the touch buffer layer can be formed using the same mask.

The touch sensing unit include a touch interlayer insulating layer, a touch electrode, and a touch insulating layer, and the micro coating layer can be disposed so as to cover an end of the touch insulating layer in the first non-active area.

The second non-active area can be disposed below the active area.

The cover layer may not be disposed in the bending area.

In the bending area, the micro coating layer can be disposed on the bank.

According to another aspect of the present disclosure, a display apparatus includes: a substrate which includes an active area in which a plurality of sub pixels is disposed, a first non-active area enclosing the active area, a bending area extending from the first non-active area to be bent, and a second non-active area extending from the bending area; a plurality of light emitting diodes which is disposed in the plurality of sub pixels on the substrate and each includes a plurality of anodes, an organic layer, and a cathode; a bank which is disposed so as to expose a part of the anodes on the plurality of anodes; a first cover layer which is disposed to extend from the active area to the first non-active area and is disposed between the bank and the organic layer; and a plurality of dams which is disposed so as to enclose the active area in the first non-active area, and the first cover layer is disposed so as to cover the plurality of dams.

The display apparatus can further comprise an encapsulation unit which includes a plurality of inorganic encapsulation layers and an organic encapsulation layer.

The organic encapsulation layer can be disposed not to extend to the plurality of dams, the plurality of inorganic encapsulation layers can be disposed so as to cover the plurality of dams and the first cover layer, and ends of the first cover layer and the plurality of inorganic encapsulation layers can be disposed on the same plane.

The display apparatus can be further comprise a second cover layer which is disposed in the second non-active area and is formed of the same material as the first cover layer.

The first cover layer and the second cover layer can be spaced apart from each other with the bending area therebetween.

The display apparatus can further comprise an encapsulation unit including a plurality of inorganic encapsulation layers and an organic encapsulation layer, a touch sensing unit disposed on the encapsulation unit in the active area, and a touch buffer layer disposed between the encapsulation unit and the touch sensing unit.

In the first non-active area, an end of the first cover layer can disposed on the same plane as an end of the touch buffer layer.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate including an active area, a first non-active area adjacent to the active area, a bending area extending from the first non-active area to be bent, and a second non-active area extending from the bending area;
a plurality of light emitting diodes disposed in the active area on the substrate, one of the plurality of light emitting diodes including an anode, an organic layer, and a cathode;
a bank disposed to cover an end of the anode; and
a cover layer disposed on the bank and extending from the active area to the first non-active area,
wherein the organic layer is disposed to cover the cover layer on the bank.

2. The display apparatus according to claim 1, wherein the cover layer is disposed so as not to overlap the anode which is exposed from the bank.

3. The display apparatus according to claim 1, further comprising:
a plurality of dams disposed to enclose the active area in the first non-active area,
wherein the cover layer extends from the active area to cover the plurality of dams.

4. The display apparatus according to claim 3, further comprising:
an encapsulation unit including a plurality of inorganic encapsulation layers and an organic encapsulation layer,
wherein the organic encapsulation layer is disposed not to extend to the plurality of dams, the plurality of inorganic encapsulation layers is disposed to cover the plurality of dams and the cover layer, and the cover layer and the plurality of inorganic encapsulation layers are in contact with each other.

5. The display apparatus according to claim 4, wherein ends of the cover layer and the plurality of inorganic encapsulation layers are disposed on a same plane or are aligned with each other.

6. The display apparatus according to claim 1, wherein the cover layer includes:
a first cover layer disposed in the active area and the first non-active area; and
a second cover layer disposed in the second non-active area and having a same material as the first cover layer.

7. The display apparatus according to claim 6, wherein the first cover layer and the second cover layer are spaced apart from each other with the bending area therebetween.

8. The display apparatus according to claim 1, further comprising:
an encapsulation unit including a plurality of inorganic encapsulation layers and an organic encapsulation layer;
a planarization layer on which the plurality of light emitting diodes is disposed; and
a micro coating layer extending from an end of the first non-active area to ends of the bending area and the second non-active area,
wherein a portion of the micro coating layer is disposed on the planarization layer in the first non-active area, and
wherein an end of the cover layer is disposed to overlap the micro coating layer.

9. The display apparatus according to claim 8, further comprising:
a touch sensing unit disposed on the encapsulation unit in the active area; and
a touch buffer layer disposed between the encapsulation unit and the touch sensing unit,
wherein in the first non-active area, the end of the cover layer is disposed on a same plane as an end of the touch buffer layer.

10. The display apparatus according to claim 1, wherein the cover layer includes an inorganic insulating material.

11. The display apparatus according to claim 1, further comprising:
a spacer disposed on the bank,
wherein the cover layer is also disposed on the spacer.

12. The display apparatus according to claim 9, wherein the cover layer includes a same material as the touch buffer layer, and the cover layer and the touch buffer layer are formed using a same mask.

13. The display apparatus according to claim 9, wherein the touch sensing unit includes a touch interlayer insulating layer, a touch electrode, and a touch insulating layer, and
wherein the micro coating layer is disposed to cover an end of the touch insulating layer in the first non-active area.

14. The display apparatus according to claim 1, wherein the second non-active area is disposed below the active area.

15. The display apparatus according to claim 1, wherein the cover layer is not disposed in the bending area.

16. The display apparatus according to claim 8, wherein in the bending area, the micro coating layer is disposed on the bank.

17. A display apparatus, comprising:
a substrate including an active area in which a plurality of sub pixels is disposed, a first non-active area enclosing the active area, a bending area extending from the first non-active area to be bent, and a second non-active area extending from the bending area;
a plurality of light emitting diodes disposed in the plurality of sub pixels on the substrate, each of the plurality of light emitting diodes including a plurality of anodes, an organic layer, and a cathode;
a bank disposed on the plurality of anodes to expose a part of the plurality of anodes;
a first cover layer disposed to extend from the active area to the first non-active area and disposed between the bank and the organic layer; and
a plurality of dams disposed to enclose the active area in the first non-active area,
wherein the first cover layer is disposed to cover the plurality of dams.

18. The display apparatus according to claim 17, further comprising:
an encapsulation unit including a plurality of inorganic encapsulation layers and an organic encapsulation layer,
wherein the organic encapsulation layer is disposed not to extend to the plurality of dams, the plurality of inorganic encapsulation layers is disposed to cover the plurality of dams and the first cover layer, and ends of the first cover layer and the plurality of inorganic encapsulation layers are disposed on a same plane.

19. The display apparatus according to claim 17, further comprising:
a second cover layer disposed in the second non-active area and including a same material as the first cover layer.

20. The display apparatus according to claim 19, wherein the first cover layer and the second cover layer are spaced apart from each other with the bending area therebetween.

21. The display apparatus according to claim 17, further comprising:
an encapsulation unit including a plurality of inorganic encapsulation layers and an organic encapsulation layer;
a touch sensing unit disposed on the encapsulation unit in the active area; and
a touch buffer layer disposed between the encapsulation unit and the touch sensing unit,
wherein in the first non-active area, an end of the first cover layer is disposed on a same plane as an end of the touch buffer layer.
